(19) United States
(12) Patent Application Publication
(10) Pub. No.: US 2006/0118811 A1
(43) Pub. Date: Jun. 8, 2006

(54) Bi-directional power switch

(76) Inventors: Shen Zheng, Oviedo, FL (US); David Okada, Chandler, AZ (US)

Correspondence Address: RICHARD I. SAMUEL;GOODWIN PROCTER L.L.P, 599 LEXINGTON AVE., NEW YORK, NY, 10022, US

(21) Appl. No.: 10/542,192

(22) PCT Filed: Feb. 4, 2004
(86) PCT No.: PCT/US04/03051

§ 371 Date: Jul. 14, 2005

Related U.S. Application Data
(60) Provisional application No. 60/444,932, filed on Feb. 4, 2003.
(60) Provisional application No. 60/501,192, filed on Sep. 8, 2003.

(51) Int. Cl. H01L 29/74

(52) U.S. Cl. 257/107

(57) ABSTRACT

A semiconductor device that is comprised to two or more MOSFETs to form a bi-directional power switch. One embodiment of the bi-directional switch is comprised of (a) a semiconductor substrate having an upper surface and a lower surface; (b) a first region of a first conductivity type in said semiconductor substrate and proximate to said upper surface; (c) a first source region and a second source region of a second conductivity type within said first region; (d) a drain region of a second conductivity type formed within said first region and proximate to said upper surface and between said first and second source regions; (e) a first source overlaying and connecting said first source region; (f) a second source overlaying and connecting said second source region; (g) a first gate above said upper surface and placed between said first source and said second source wherein said first gate overlays a portion of said first source region and said drain region; (h) a second gate above said upper surface and placed between said second source and said first gate wherein said second gate overlays a portion of said second source region and said drain region.

### CROSS-REFERENCE TO RELATED APPLICATIONS

This application claims the benefit of U.S. Provisional Application 60/444,943, filed Feb. 4, 2003 and U.S. Provisional Application 60/501,192, filed Sep. 8, 2003, each of which are hereby incorporated by reference in its entirety.

### BACKGROUND OF THE INVENTION

I. Field of the Invention

The present invention generally relates to the field of semiconductor devices and more particularly to bi-directional power switches.

2. Related Background Art

Power MOSFETs (metal-oxide-semiconductor field-effect transistor) are used to create monolithic bi-directional power switches (“BDS”). Bi-directional switches are used in many applications, such as in battery charging circuitry to permit controlling the discharging and charging of batteries. For instance, lithium-ion batteries should not continue to be charged after they are fully charged to prevent dangerous and catastrophic failures and fires.

Two types of bi-directional switches are currently available. The first type is exemplified by products such as Siliconix's Si8900EDB and International Rectifier's FlipFET. In these types of switches, the drains of two MOSFETs are connected together through a common silicon substrate as shown in FIG. 2. The second type is exemplified by products such as Fairchild's FDZ2551N where the drains are connected through an expensive copper package.

In both cases, current flow for these MOSFETs goes from the source to the drain via the substrate. When creating bi-directional switches, two vertical trench MOSFETS are used and connected via a common drain. The first type of bi-directional switch (e.g. Siliconix's Si8900EDB and International Rectifier's FlipFET) have higher R_{DSON} (static drain-source on-resistance). This is because using vertical trench MOSFETs creates long current pathways from the source of the first MOSFET to the source of the second MOSFET. In particular, current first travels down vertically, then horizontally through the substrate then back up vertically. This causes the current to travel through high resistance structures resulting in, inter alia, high R_{DSON} values. The second type has a lower R_{DSON} but a high cost due to the additional copper package.

Accordingly, there is a need to provide bi-directional power switches with efficient current flow and without the need for costly packaging. There is also a need for bi-directional switches with improved (i.e., lower) on-resistance and monolithic structures.

### BRIEF SUMMARY OF THE INVENTION

According to an embodiment of the present invention, a lateral MOSFET bi-directional switch is disclosed. In accordance with one aspect of the present invention, a semiconductor device is disclosed with (a) a semiconductor substrate having an upper surface and a lower surface; (b) a first region of a first conductivity type in said semiconductor substrate and proximate to said upper surface; (c) a first source region and a second source region of a second conductivity type within said first region; (d) a drain region of a second conductivity type formed within said first region and proximate to said upper surface and between said first and second source regions; (e) a first source overlaying and connecting said first source region; (f) a second source overlaying and connecting said second source region; (g) a first gate above said upper surface and placed between said first source and said second source wherein said first gate overlays a portion of said first source region and said drain region; (h) a second gate above said upper surface and placed between said second source and said first gate wherein said second gate overlays a portion of said second source region and said drain region.

In accordance with another aspect of the present invention, a semiconductor device is disclosed with (a) a semiconductor substrate having an upper surface and a lower surface; (b) a first region of a first conductivity type in said semiconductor substrate and proximate to said upper surface; (c) a second region and a third region of a second conductivity type within said first well region; (d) a first source region of a first conductivity type within said second region and a second source region having a first conductivity type within said third region; (e) a first source overlaying and connecting said first source region; (f) a second source overlaying and connecting said second source region; (g) a first gate above said upper surface and placed between said first source and said second source wherein said first gate overlays a portion of said first source region and said second region; (h) a second gate above said upper surface and placed between said second source and said first gate wherein said second gate overlays a portion of said second source region and said third region.

In accordance with yet another aspect of the present invention, a semiconductor device is disclosed with (a) a semiconductor substrate having an upper surface and a lower surface; (b) a first region and a second region of a first conductivity type in said semiconductor substrate and proximate to said upper surface; (c) a first connecting region within said first region of a first conductivity type and a first source region within said first region of a second conductivity type; (d) a second connecting region within said second region of a first conductivity type and a second source region within said second region of a second conductivity type; (e) a first source overlaying and connecting said first source region; (f) a second source overlaying and connecting said second source region; (g) a first gate above said upper surface and placed between said first source and said second source wherein said first gate overlays a portion of said first source region and said first region; (h) a second gate above said upper surface and placed between said second source and said first gate wherein said second gate overlays a portion of said second source region and said second region.

In accordance with yet another aspect of the present invention, a semiconductor device is disclosed with (a) a semiconductor substrate having an upper surface and a lower surface; (b) a first region of a first conductivity type proximate to said upper surface; (c) a plurality of second regions of a second conductivity type within said first well region, each of said second region having a first source region of a first conductivity type within said second regions; (d) a plurality of third regions of a second conductivity type within said first region, each of said third region having a second source region of a first conductivity type within said third region; (e) a plurality of first sources overlaying and connecting said plurality of said first source regions; (f) a plurality of second sources overlaying and connecting said plurality of said second source regions; (g) a plurality of first gates above said upper surface wherein each first gate is placed between a first source and a second source and overlays a portion of said first source region and said second region; (h) a plurality of second gates above said upper surface wherein each second gate is placed between a second source and first gate and overlays a portion of said second source region and said third region.

In accordance with yet another aspect of the present invention a semiconductor device is disclosed having a plurality of first sources and a plurality of second sources wherein current flows from a first source to an associated second source. The semiconductor device have the first sources dispersed among the second sources. The semiconductor devide may also have current paths from different first sources to associated second sources that are substantially similar.

### BRIEF DESCRIPTION OF THE DRAWINGS

FIG. 1 is an exemplary application of bi-directional switches.

FIG. 2 is a prior art trench MOSFET bi-directional switch.

FIG. 3 is a cross sectional view of a MOSFET in accordance with an embodiment of the present invention.

FIG. 4 is a cross sectional view of a MOSFET in accordance with another embodiment of the present invention.

FIG. 5a is a cross sectional view of one cell of a bi-directional switch in accordance with an embodiment of the present invention.

FIG. 5b is a top view one embodiment of FIG. 5a.

FIG. 5c is a cross sectional view of one cell of a bi-directional switch in accordance with an embodiment of the present invention.

FIG. 6 a cross sectional view of one cell of a bi-directional switch in accordance with an embodiment of the present invention.

FIG. 7 is a cross sectional view of a bi-directional switch composed of multiple cells.

FIG. 8 is a cross sectional view of a bi-directional switch using multiple cells and conventional technology in accordance with an embodiment of the present invention.

FIG. 9a is a top view of solder bumps of an exemplary device without access to the drain.

FIG. 9b is a top view of solder bumps of an exemplary device with access to the drain.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DESCRIPTION OF THE INVENTION

The preferred embodiment of the present invention uses conventional CMOS fabrication processes to fabricate a semiconductor device embodying the present invention to reduce the costs of production. In accordance with one aspect of the present invention, however, only one type of MOSFETs (either an n-channel or p-channel MOSFET) is made on the die. Since the device of the present invention only consists of parallel n-channel or p-channel transistors, the problem of latch-up is avoided.

In one embodiment, multiple bi-directional switches are fabricated on a single monolithic chip and connected in parallel. Preferably, these bi-directional switches are interconnected by runners that are short and wide. These interconnections are disclosed in more detail in U.S. patent application Ser. No. 10/601,121 filed Jun. 19, 2003 and U.S. Provisional Application 60/416,942 filed Oct. 8, 2002, both incorporated herein by reference in their entirety.

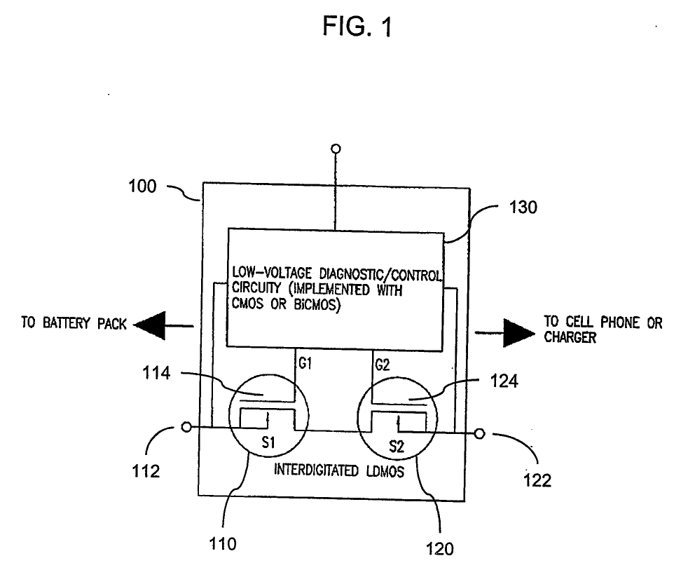

Referring now to FIG. 1, there is shown an exemplary application for the present invention. Battery charging circuitry 100 includes MOSFET 110, having a source 112 (S1) and a gate 114 (G1), and MOSFET 120, having a source 122 (S2) and a gate 124 (G1). Source 112 is connected to a battery and source 122 is connected to the device requiring the battery or a charger or both. Control circuit 130 is connected to sources 112 and 122 and gates 114 and 124. Control circuit 130 monitors sources 112 and 122 and, depending on factors such as the voltage of sources 112 and 122 and the state of the battery or charger. Control circuit 130 biases gates 114 and 124 to allow the battery or charger to power the device or to allow the charger to charge the battery.

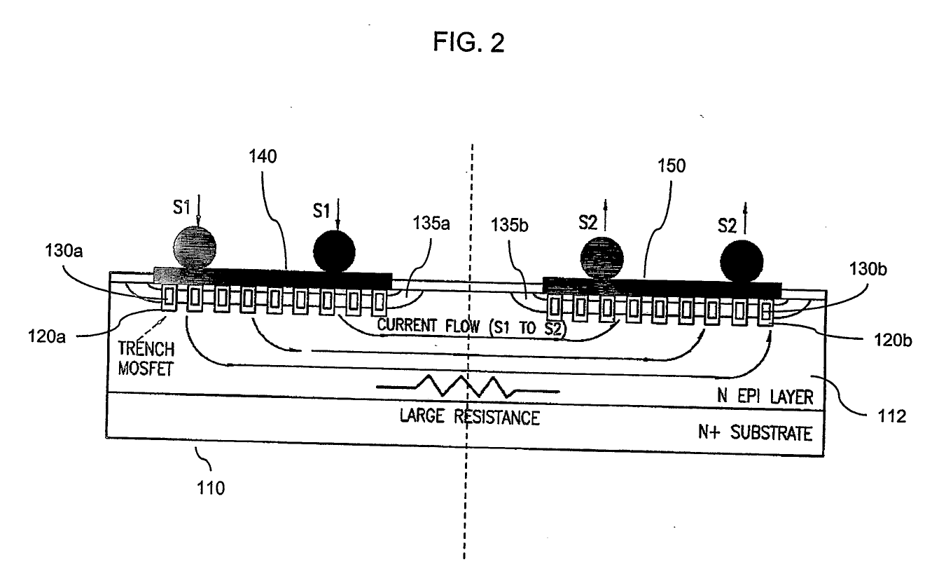

FIG. 2 shows a prior art bi-directional switch monolithic circuit such as Siliconix's Si8900EDB and International Rectifier's FlipFET. These devices typically have a substrate 110 and an epi layer 112, which, in this example, is of n conductivity type with N+ and N majority carrier concentrations, respectively. These are vertical trench MOSFET devices using a number of parallel trench MOSFETs 120a and 120b in p-wells 135a and 135b. Trench MOSFETs 120a and 120b are controlled by gates 130a and 130b, respectively. Current flows through sources 140 (S1) and 150 (S2), which in FIG. 2 is shown as flowing from source 140, down through trench MOSETs 120a, down to and across epi layer 112, and back up to source 150 through trench MOSFETS 120b. In the prior art example, S1 and S2 are in two sections of the die, thus there is a long current path between S1 and S2 which constitute about 50% of the total resistance.

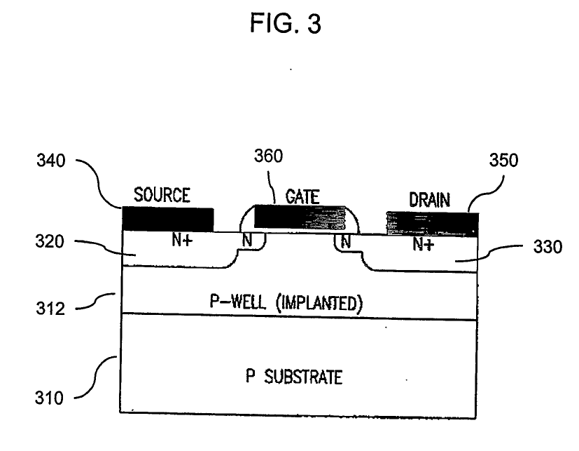

FIGS. 3-6 shows different aspects of the present invention, in particular, different MOSFETs used in the present invention. In particular, the MOSFET of FIG. 3 has a substrate 310 of p conductivity type and implanted P-well 312. Formed in P-well 312 are regions 320 and 330 of n conductivity type having N+ and N majority carrier concentrations. Although wells are described in this and other embodiments, one skilled in the art may instead use epitaxial regions or use other methods to dope the appropriate regions with the desired conductivity type instead of using implanted wells.

Source 340 is placed over region 320, drain 350 is placed over region 330, and gate 360 is placed, with an insulating layer (e.g. SiO₂), between source 340 and drain 350. In this embodiment gate 360 overlays that portion of P-well 312 that is proximate to the surface under gate 360. Gate 360 also partially extends over those sections of regions 320 and 330 having the N majority carrier concentrations.

In operation, when gate 360 is biased, an n-channel forms under gate 360 thereby permitting current to flow between source 340 and drain 350 via region 320, the n-channel under gate 360 (not shown) and region 330.

The MOSFET shown in FIG. 3 has the advantages of an NMOS structure, low R_{ON} (e.g. 5-20 mΩ mm2) for 7-10V breakdown voltage, extremely low Q_{g}, and requires only 4 masks to fabricate (excluding metal layers). These are only exemplary numbers and may vary depending on the design.

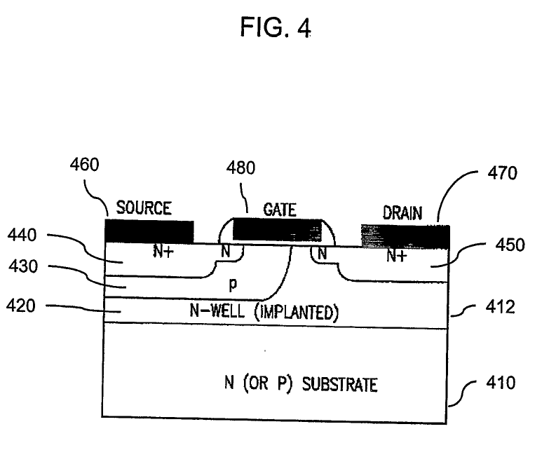

The MOSFET of FIG. 4 has a substrate 410 of n or p conductivity type (N or P majority carrier concentrations) and an implanted N-well 420. Formed in N-well 420 is p-well 430. Formed in p-well 430 and N-well 420 are regions 440 and 450, which are of n conductivity type having N+ and N majority carrier concentrations.

Source 460 is placed over region 440 and drain 470 is placed over region 450. Gate 480 is placed, with an insulating layer (e.g. SiO₂), between source 460 and drain 470. Gate 480 overlays a portion of region 440, a portion of p-well 430 that extends to the surface under gate 480, a portion of N-well 420 which also extends to the surface under gate 480, and a portion of region 450.

In operation, when gate 480 is biased, an n-channel forms under gate 480 in p-well 430 that extends under gate 480 thereby permitting current to flow between source 460 and drain 470 via region 440, the n-channel (not shown) formed under gate 480 in p-well 430, N-well 420 and region 450.

The MOSFET shown in FIG. 4 has the advantage of a DMOS structure, reduced E-Field, low R_{ON} (e.g. 10-40 mΩ mm2) for 12-100V breakdown voltage, improved safe operating area (“SOA”), and requires only 5 masks (excluding metal layers). These are only exemplary numbers and may vary depending on the design.

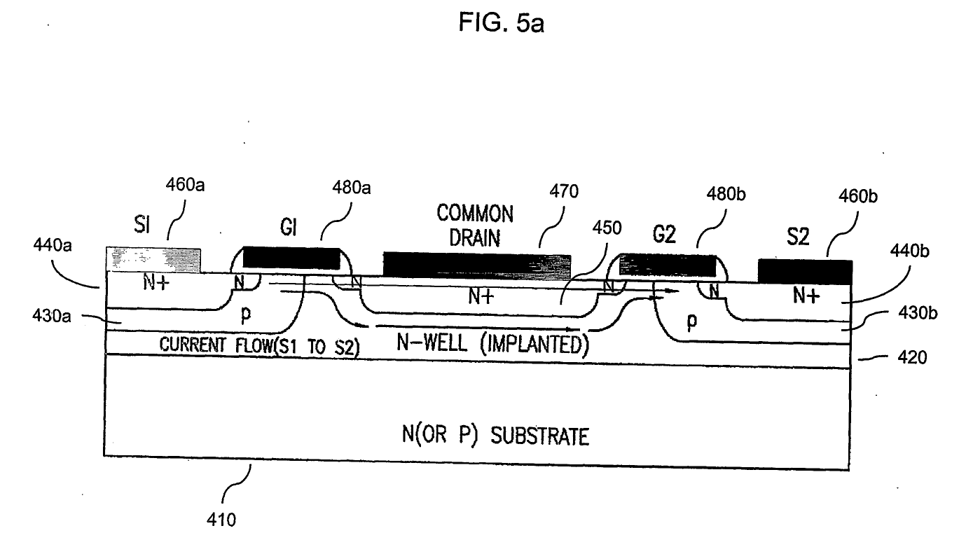

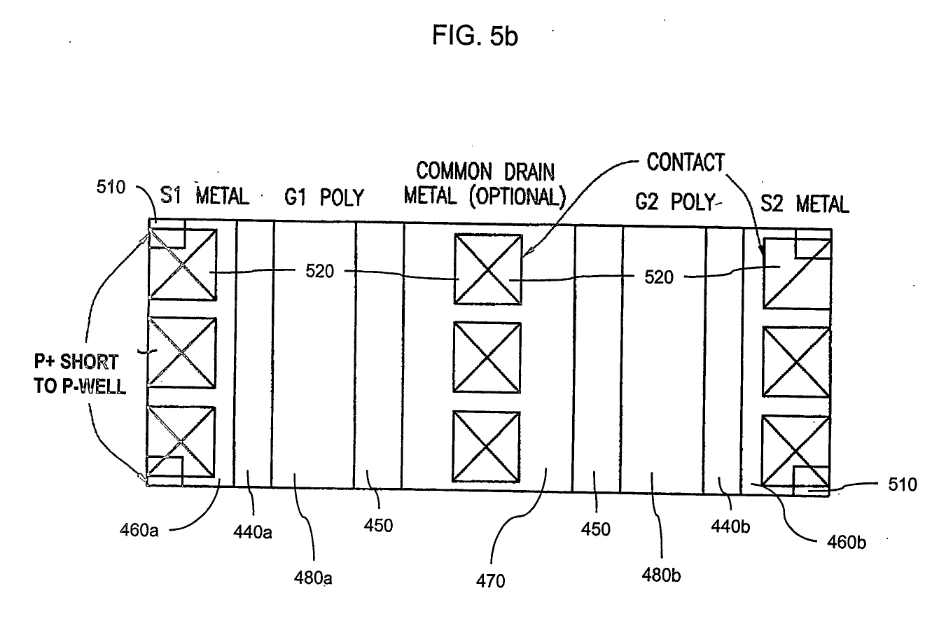

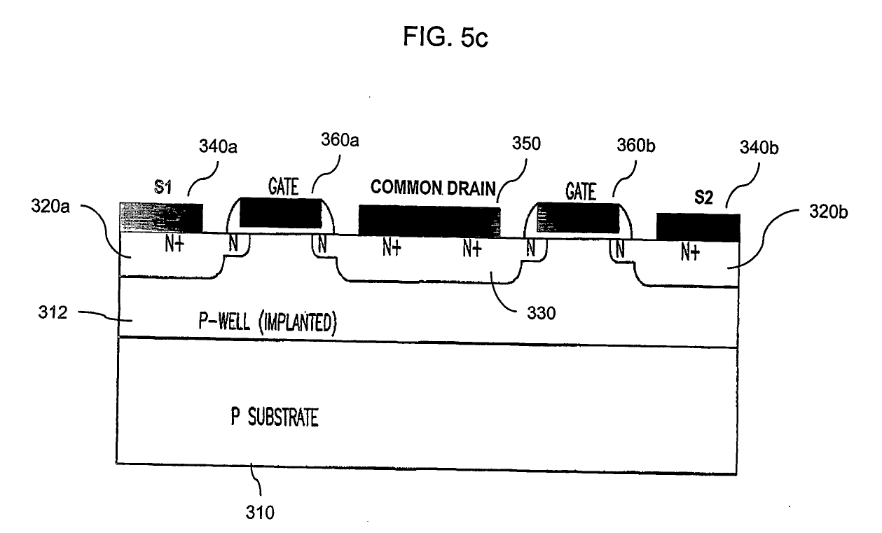

FIG. 5a shows one cell of a MOSFET bi-directional switch using two of the MOSFET shown in FIG. 4 and formed with a common drain. Specifically, there is shown a substrate 410 of n or p conductivity type (N or P majority carrier concentrations) and implanted N-well 420. Formed in N-well 420 are p-wells 430a and 430b, respectively. Formed in p-wells 430a, 430b and N-well 420 are regions 440a, 440b and 450, which are of n conductivity type having N+ and N majority carrier concentrations. Not shown are P+ regions electrically connecting source 460a to p-well 430a and source 460b to p-well 430b to bring the sources and their respective p-wells to the same potential.

Sources 460a and 460b are placed over regions 440a and 440b, respectively. Drain 470 is placed over region 450. Gate 480a is placed, with an insulating layer (e.g. SiO₂), between source 460a and a drain 470. Gate 480a overlays a portion of region 440a, a portion of p-well 430a that extends to the surface under gate 480a, a portion of N-well 420 which also extends to the surface under gate 480a, and a portion of region 450. Gate 480b is placed, with an insulating layer (e.g. SiO₂), between source 460b and drain 470. Gate 480b overlays a portion of region 440b, a portion of p-well 430b that extends to the surface under gate 480b, a portion of N-well 420 which also extends to the surface under gate 480b, and a portion of region 450. Use of drain 470 is optional.

In operation, when gates 480a and 480b are properly biased for bi-directional use, an n-channel forms under gate 480a in p-well 430a that extends under gate 480a and under gate 480b in p-well 430b that extends under gate 480b. This permits current to flow between source 460a and source 460b via region 440a, the n-channel (not shown) formed under gate 480a in p-well 430a, N-well 420 and region 450, the n-channel (not shown) formed under gate 480b in p-well 430b, and region 440b. FIG. 5a shows current flowing, for instance, from source 460a to source 460b.

In another embodiment of FIG. 5a, region 450 is comprised of part of N-well 420—there is no further doping or implanting to change the carrier concentrations beyond what it is for N-well 420. In this type of embodiment, current flows between source 460a and source 460b across that portion of N-well 420 near the upper surface.

FIG. 5b shows an exemplary top view of one embodiment of the bi-directional switch cell of FIG. 5a using the same labels to identify analoguous parts. As can be seen, the source, gate and drain regions in this embodiment take the form of rectangular “fingers”. There is also shown shorts 510 which allow sources 460a and 460b to contact the p-well 430a and 430b, respectively. Contacts 520 are used to connect the sources, and drain if desired, to other circuitry, other sources or drains or to contact pads.

FIG. 5c shows one cell of a MOSFET bi-directional switch using two of the MOSFET shown in FIG. 3 and formed with a common drain. Specifically, there is shown a substrate 310 of p conductivity type and implanted P-well 312. Formed in P-well 312 are regions 320a, 320b and 330, of n conductivity type having N+ and N majority carrier concentrations.

Sources 340a and 340b are placed over regions 320a and 320b, respectively. Drain 350 is placed over region 330. Gate 360a is placed, with an insulating layer (e.g. SiO₂), between source 340a and drain 350. Gate 360a overlays aportion of region 320a, a portion of P-well 312 that extends to the surface under gate 360a, and a portion of region 330. Gate 360b is placed, with an insulating layer (e.g. SiO₂), between source 340b and drain 350. Gate 360b overlays a portion of region 320b, a portion of P-well 312 that extends to the surface under gate 360b, and a portion of region 330. Use of drain 350 is optional.

In operation, when gates 360a and 360b are properly biased for bi-directional use, an n-channel forms under gate 360a in the portion of P-well 312 that extends under gate 360a and under gate 360b in the portion of P-well 312 that is extends under gate 360b. This permits current to flow between source 340a and source 340b via region 320a, the n-channel (not shown) formed under gate 360a in P-well 312, region 330, the n-channel (not shown) formed under gate 360b in P-well 312, and region 320b.

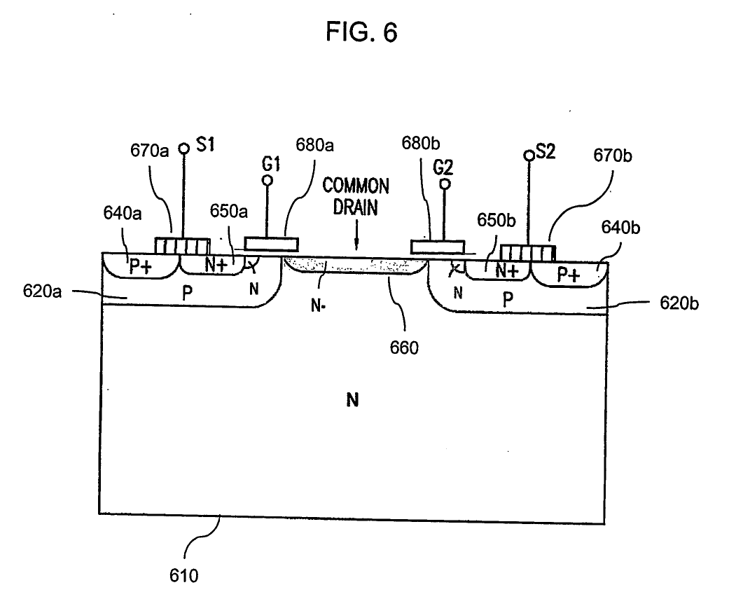

FIG. 6 shows another embodiment one cell of a MOSFET bi-directional switch in accordance with the present invention. In particular, the cell has a substrate 610 of n conductivity type. Formed in substrate 610 are P-wells 620a and 620b. P-well 620a has formed in it P+ region 640a, and region 650a of n conductivity type having N+ and N majority carrier concentrations. P-well 620b has formed in it P+ region 640b, and region 650b of an n conductivity type having N+ and N majority carrier concentrations.

Source 670a is placed over P+ region 640a and the portion of region 650a having the N+ majority carrier concentrations. Source 670b is placed over P+ region 640b and the portion of region 650b having the N+ majority carrier concentration. The P+ regions allow the sources to contact their respective P-wells. Region 660 of n conductivity type (N majority carrier concentration) is formed in substrate 610. Gate 680a is placed, with an insulating layer (eg. SiO₂), between source 670a and gate 680b and overlays a portion of region 650a, P-well 620a and region 660. Gate 680b is placed, with an insulating layer (e.g. SiO₂), between source 670b and gate 680a and overlays a portion of region 650b, P-well 620b and region 660. Region 660 is essentially a common drain—access to the drain is optional.

In another embodiment of FIG. 6, region 660 is comprised of part of substrate 610—there is no further doping or implantating to change the carrier concentrations beyond what it is for substrate 610. In this type of embodiment, current flows between source 670a and source 670b across that portion the substate 610 near the upper surface.

In operation, when gates 680a and 680b are properly biased for bi-directional use, an n-channel forms under gate 680a in that portion of P-well 620a that extends under gate 680a, and an n-channel forms under gate 680b in that portion of P-well 620b that extends under gate 680b. This permits current to flow between source 670a and source 670b via region 650a, the n-channel (not shown) formed under gate 680a in P-well 620a, region 660, the n-channel (not shown) formed under gate 680b in P-well 620b, and region 650b.

### EXAMPLE 1

Referring to FIGS. 1, 5a, 5c and 6, there will now be discussed an example using the present invention in a battery powered device that can be used to charge the battery. Using the application of FIG. 1, the bi-directional switch of FIG. 5a has sources S1 and S2 (sources 460a and 460b, respectively) and gates G1 and G2 (gates 480a and 480b, respectively). The bi-directional switch of FIG. 5c has sources S1 and S2 (sources 340a and 340b, respectively) and gates G1 and G2 (gates 360a and 360b, respectively). Likewise, the bi-directional switch of FIG. 6 has sources S1 and S2 (sources 670a and 670b, respectively) and gates G1 and G2 (gates 680a and 680b, respectively). The battery is connected to source S1. The device or a charger or both is connected to source S2. Control circuit 130 is connected to sources S1 and S2 and gates G1 and G2.

If the battery has sufficient energy to drive the device, control circuit 130 biases gate G1 relative to source S1 and gate G2 relative to source S2. This permits current to flow from the battery through the bi-directional switch to the device.

If the battery has insufficient energy to drive the device, for instance, if the voltage is too low, control circuit 130 removes the bias from gate G1 thereby stopping current from flowing from S1 and isolating the battery from the rest of the device. This helps prevent the device from operating on too low a voltage which could cause malfunctions, and also prevents the battery from draining itself too low which can cause damage to the battery. Gate G1 may also be closed in situations where the device is being run from the charger to prevent using the battery during such operation.

If the battery is being charged, control circuit 130 biases gate G1 relative to source S1 and gate G2 relative to source S2. This permits current to flow from the charger through the bi-directional switch to the battery.

If the battery is fully charged, control circuit 130 closes gate G2 to prevent overcharging the battery, which could cause a catastrophic failure or a fire for certain types of batteries such as lithium ion batteries.

Table 1 compares the characteristics of certain prior art devices against bi-directional switches formed with the embodiment shown in FIGS. 5a (drain access) and 6 (no drain access)(referred to in Table 1 as LateralDiscrete™):

TABLE 1

| | | R_{DSON} | | | |
|---|---|---|---|---|---|
| | | (typical) | Rated I (A) | Solder Bump | Die Size |
| Device | Technology | (@4.5) | (Pulse/Cont) | (Each FET) | (mm²) |
| Fairchild | Vertical Trench | 15 mΩ | 20 A/9 A | S = 5, D = 3, G = 1 | Si: 5.2 mm² |
| FDZ2551N | Cu Carrier/BGA | | | (3 × 6) | Total: 10 mm² |
| Siliconix | Vertical Trench | 20 mΩ | 10 A/5.4 A | S = 4, D = 0, G = 1 | 8 mm² |
| S18900EDB | Solder Bump | | | (2 × 5) | (4 × 2 mm²) |
| IR | Vertical Trench | 20 mΩ | — | S = 7, D = 0, G = 1 | 9.7 mm² |
| FlipFET | Solder Bump | | | (4 × 4) | (3.1 × 3.1 mm²) |
| LateralDiscrete | Lateral DMOS | 10 mΩ | 10 A/5.4 A | S = 7, D = 4, G = 1 | 6 mm² |
| w/Drain Acess | Solder Bump | | | (6 × 4) | (3 × 2 mm²) |
| LateralDiscrete | Lateral DMOS | 15 mΩ | 10 A/5.4 A | S = 7, D = 0, G = 1 | 4 mm² |
| w/o DrainAcess | Solder Bump | | | (4 × 4) | (2 × 2 mm²) |

1. A specific RDSON of 30 mΩ mm2 is assumed.
2. The die sizes for LateralDiscrete are limited by the maximum current allowed for each bump rather than RDSON requirement. A 0.5 mm pitch is assumed for solder bumps and seven (7) source bumps are used for a peak pulse current of 10 A (same as IR).

As can be seen, the present invention provides a smaller on-resistance for a given die size. It also allows the use of devices that provide access to the drain or devices with no access to the drain.

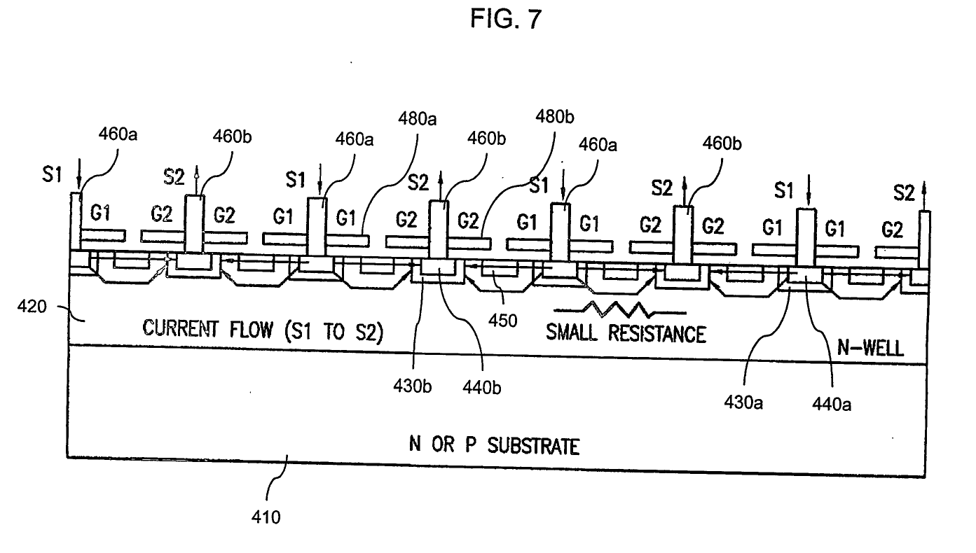

In accordance with another aspect of the present invention multiple cells are used to create a bi-directional switch able to handle large current flows with reduced on-resistance by interleaving multiple sources and gates. This design improves the on-resistance by reducing the current path, which reduces the on resistance, and also by connecting the cells in parallel, which connects the resistance in parallel which also dramatically reduces the resistance. An exemplary embodiment is shown in FIG. 7 using the cells of FIG. 5a and using the same labels to identify similar parts. As shown, current flows from sources S1 (460a) to the nearest source S2 (460b). As will be apparent to one skilled in the art, the cells shown in FIGS. 5c and 6 can also be used to create bi-directional switches using multiple cells in a manner similar to that shown in FIG. 7 with respect to the cell of FIG. 5a.

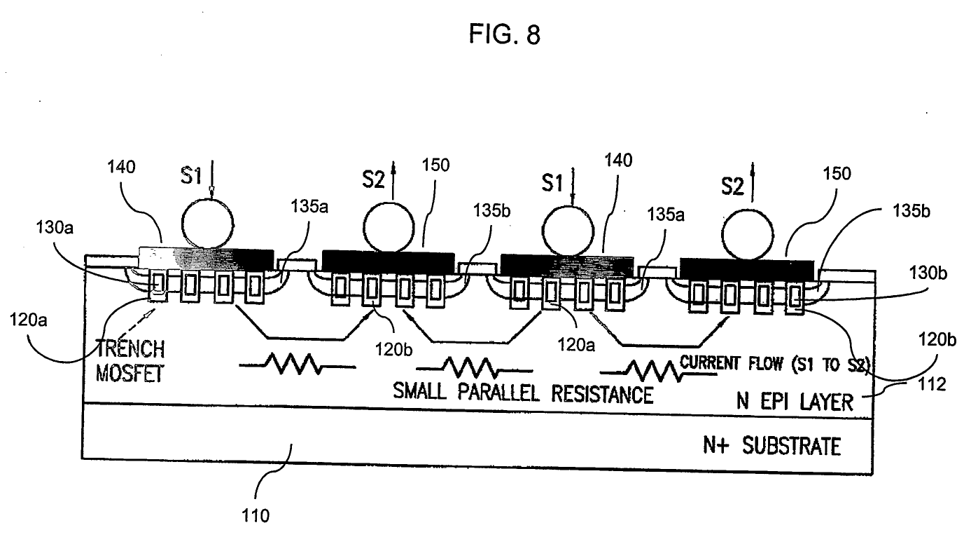

FIG. 8 shows that using multiple cells and interleaving sources and gates can also be applied to conventional technology to reduce on-resistance. In this exemplary embodiment, the prior art design of FIG. 2 (using trench MOSFETs or planar DMOS structures) typically is composed of two die or areas. One die has many trench MOSFETs to create the first source, the second die likewise has many trench MOSFETs to create a second source. In accordance with another aspect of the present invention, these large source areas are subdivided into smaller and multiple sources S1 (140) and S2 (150) groupings and alternately arranged to interleave the sources and gates. This design reduces the current path between sources, which reduces the on-resistance, and connects the smaller S1 and S2 cells in parallel thereby further reducing on-resistance. In the exemplary embodiment, current flows from sources S1 to the nearest source S2.

With reference to FIGS. 7 and 8, even though source S1 and S2 (and their associated underlying regions) are shown interleaved in a 1:1 fashion the scoped of the invention is not limited in such a manner; sources S1 and S2 may be distributed in other patterns and ratios without departing from the scope of the invention. Sources S1 may be dispersed among sources S2 rather than interleaved in an interdigitated fashion. Likewise a source S1 may be associated with several sources S2 such that current flows between that source S1 and certain associated sources S2. In yet another embodiment, the current path from a source S1 to one or more associated sources S2 is substantially similar to current paths from another source S1 to its associated sources S2.

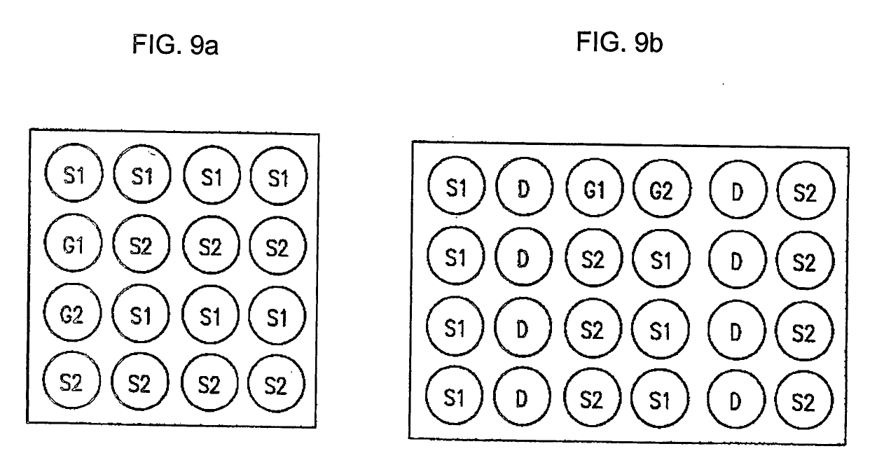

In embodiments using multiple cells (and interleaved sources and gates), multiple layers (preferably metal) are used to interconnect sources S1 together, interconnect sources S2, interconnect gates G1, interconnect gates G2, and to interconnect drains if used. The performance of these interconnections can be improved using the novel interconnections disclosed in U.S. patent application Ser. No. 10/601,121. FIG. 9a shows a top view showing the solder bumps for a device of the present invention that does not provide access to the drain. FIG. 9b shows a top view showing the solder bumps for a device of the present invention that provides access to the drain.

It should be apparent to those skilled in the art that the foregoing are illustrative only and not limiting, having been presented by way of example only. All the features disclosed in this description may be replaced by alternative features serving the same purpose, and equivalents or similar purpose, unless expressly stated otherwise. For instance, one skilled in the art can reverse the conductivity types shown in these embodiments as needed and without departing from the spirit or scope of the invention. Using FIG. 3 as an example, substrate 310 and P-well 312 can be of n conductivity type, and regions 320 and 330 can be of p conductivity type having P+ and P majority carrier concentrations instead of N+ and N. Moreover, the implanted wells may be replace by doped expitaxial layers or other methods used which impart the same conductivity type without departing from the scope of the present invention. Again using FIG. 3 as an example, P-well 312 may be formed using, for instance, a doped epitaxial process rather than an implanting dopants. Therefore, numerous other embodiments of the modifications thereof are contemplated as falling within the scope of the present invention as defined herein and equivalents thereto.

What is claimed is:

1. A semiconductor device comprising:
a. a semiconductor substrate having an upper surface and a lower surface;
b. a first region of a first conductivity type in said semiconductor substrate and proximate to said upper surface;
c. a first source region and a second source region of a second conductivity type within said first region;
d. a drain region of a second conductivity type formed within said first region and proximate to said upper surface and between said first and second source regions;
e. a first source overlaying and connecting said first source region;
f. a second source overlaying and connecting said second source region;
g. a first gate above said upper surface and placed between said first source and said second source wherein said first gate overlays a portion of said first source region and said drain region;
h. a second gate above said upper surface and placed between said second source and said first gate wherein said second gate overlays a portion of said second source region and said drain region.

2. A semiconductor device comprising:
a. a semiconductor substrate having an upper surface and a lower surface;
b. a first region of a first conductivity type in said semiconductor substrate and proximate to said upper surface;
c. a second region and a third region of a second conductivity type within said first well region;
d. a first source region of a first conductivity type within said second region and a second source region having a first conductivity type within said third region;
e. a first source overlaying and connecting said first source region;
f. a second source overlaying and connecting said second source region;
g. a first gate above said upper surface and placed between said first source and said second source wherein said first gate overlays a portion of said first source region and said second region;
h. a second gate above said upper surface and placed between said second source and said first gate wherein said second gate overlays a portion of said second source region and said third region.

3. A semiconductor device of claim 2 further comprising:
a. a drain region of a first conductivity type formed within said first region and proximate to said upper surface and placed between said second and third regions.

4. A semiconductor device comprising:
a. a semiconductor substrate having an upper surface and a lower surface;
b. a first region and a second region of a first conductivity type in said semiconductor substrate and proximate to said upper surface;
c. a first connecting region within said first region of a first conductivity type and a first source region within said first region of a second conductivity type;
d. a second connecting region within said second region of a first conductivity type and a second source region within said second region of a second conductivity type;
e. a first source overlaying and connecting said first source region;
f. a second source overlaying and connecting said second source region;
g. a first gate above said upper surface and placed between said first source and said second source wherein said first gate overlays a portion of said first source region and said first region;
h. a second gate above said upper surface and placed between said second source and said first gate wherein said second gate overlays a portion of said second source region and said second region.

5. A semiconductor device of claim 4 further comprising:
a. a drain region of a second conductivity type formed within said substrate and proximate to said upper surface and placed between said first and second well regions.

6. A semiconductor device comprising:
a. a semiconductor substrate having an upper surface and a lower surface;
b. a first region of a first conductivity type proximate to said upper surface;
c. a plurality of second regions of a second conductivity type within said first well region, each of said second region having a first source region of a first conductivity type within said second regions;
d. a plurality of third regions of a second conductivity type within said first region, each of said third region having a second source region of a first conductivity type within said third region;
e. a plurality of first sources overlaying and connecting said plurality of said first source regions;
f. a plurality of second sources overlaying and connecting said plurality of said second source regions;
g. a plurality of first gates above said upper surface wherein each first gate is placed between a first source and a second source and overlays a portion of said first source region and said second region;
h. a plurality of second gates above said upper surface wherein each second gate is placed between a second source and first gate and overlays a portion of said second source region and said third region.

7. A semiconductor device in accordance with claim 6 further comprising:
a. a plurality of drain regions of a first conductivity type and within said first region wherein each drain region is between a second region and a third region.

8. A semiconductor device comprising:
a. a plurality of first sources;
b. a plurality of second sources wherein current flows from a first source to an associated second source.

9. A semiconductor device in accordance with claim 8 wherein said first sources are dispersed among said second sources.

10. A semiconductor device in accordance with claim 8 wherein current paths from different first sources to associated second sources are substantially similar.
